(19) United States
(12) Patent Application Publication
(10) Pub. No.: US 2026/0098198 A1
(43) Pub. Date: Apr. 9, 2026

(54) THERMALLY CONDUCTIVE GREASE AND ELECTRONIC DEVICE

(71) Applicant: DENKA COMPANY LIMITED, Tokyo (JP)

(72) Inventors: Kazuyuki IGARASHI, Tokyo (JP); Takayuki IWASAKI, Tokyo (JP)

(73) Assignee: DENKA COMPANY LIMITED, Tokyo (JP)

(21) Appl. No.: 19/143,169

(22) PCT Filed: Dec. 20, 2023
(86) PCT No.: PCT/JP2023/045666

§ 371 Date: Jun. 25, 2025

(30) Foreign Application Priority Data
Dec. 26, 2022 (JP) 2022-208955

(51) Int. Cl. C09K 5/10; H10W 40/25

(52) U.S. Cl. CPC C09K 5/10; H10W 40/251

(57) ABSTRACT

There is provided a thermally conductive grease containing: an alkenyl group-containing organopolysiloxane A having two or more alkenyl groups; an alkenyl group-containing organopolysiloxane B having two or more alkenyl groups; and a thermally conductive powder, in which viscosity ηA of the alkenyl group-containing organopolysiloxane A at 25° C. and a shear rate of 10 s⁻¹ is smaller than viscosity ηB of the alkenyl group-containing organopolysiloxane B at 25° C. and a shear rate of 10 s⁻¹, and a ratio (Ti value) of viscosity η1 at a shear rate 1 s⁻¹ to viscosity η10 at 25° C. and a shear rate of 10 s⁻¹ is 3.0 or more.

### TECHNICAL FIELD

The present invention relates to a thermally conductive grease and an electronic device.

### BACKGROUND ART

Along with miniaturization and high output of heat-generating electronic components such as a central processing unit (CPU) of electronic devices, the amount of heat generated from these electronic components per unit area has become very large in recent years, and the amount of heat reaches about 20 times the amount of heat generated by an iron. In order to use such a heat-generating electronic component and to safely manage the electronic component for a long period of time not to fail, a cooling mechanism for the heat-generating electronic component is required. In general, a metal heat sink or a housing is used as a cooling unit for cooling. At this time, when the heat-generating electronic component and the cooling unit are brought into contact with each other without any material interposed therebetween, air exists at the interface between the heat-generating electronic component and the cooling unit when viewed microscopically, which hinders thermal conduction. Therefore, a thermally conductive material for efficiently transferring heat from the heat-generating electronic component to the cooling unit is used.

Meanwhile, in recent years, the temperature of an element has reached 200° C. or higher along with high-speed processing and miniaturization of electronic devices using SiC or GaN power semiconductors, and the demand for thermally conductive materials having excellent thermal conductivity is increasing even further. In addition, in a case where a thermally conductive pad or a thermally conductive sheet is used as the thermally conductive material, there is a limit to the thickness, and it is difficult to use the thermally conductive pad or the thermally conductive sheet in a situation where a very thin thickness is required. Therefore, a heat dissipation grease is suitably used. Since the heat dissipation grease is liquid, the heat dissipation grease can be thinned, and can be applied to fill the space between the heat-generating electronic component and the cooling unit, and thus, the heat dissipation grease is increasingly used for various electronic components.

On the other hand, since the heat dissipation grease is liquid as described above, in a case where a place where the thickness of a gap between the heat-generating electronic component and the cooling unit is large or a surface to which the heat dissipation grease is applied is used in the vertical placement (in a case where the heat dissipation grease is used between two planes perpendicular to the ground), there is a problem that the heat dissipation grease drips down due to vibration or the like of the electronic device. Once the dripping occurs, heat cannot be efficiently released from the heat-generating component to the metal housing, which easily leads to failure of the heat-generating component.

Therefore, in recent years, a method for suppressing such dripping has been proposed. For example, Patent Literature 1 discloses a thermally conductive silicone putty composition in which a specific organopolysiloxane is mixed and aluminum hydroxide having a relatively small particle size is mixed in a certain ratio or more in the thermally conductive silicone putty composition for the purpose of providing a thermally conductive silicone putty composition excellent in displacement resistance.

In addition, Patent Literature 2 discloses a silicone composition obtained by mixing an iron oxide powder having a specific average particle size in a thermally conductive silicone composition at a specific ratio for the purpose of providing a silicone composition that gives a heat dissipation grease excellent in displacement resistance.

Furthermore, Patent Literature 3 discloses a thermally conductive silicone composition comprising a predetermined organopolysiloxane, a predetermined thermally conductive filler, and an organic peroxide having a predetermined half-life temperature from the viewpoint of suppressing displacement (pump-out phenomenon).

### CITATION LIST

### Patent Literature

Patent Literature 1: JP 2017-002179 A
Patent Literature 2: JP 2015-140395 A
Patent Literature 3: JP 2018-076423 A

### SUMMARY OF INVENTION

### Technical Problem

However, since the thermal conduction properties are greatly affected by the type and particle size of the thermally conductive powder, improvement of thermal conduction properties cannot be achieved when it is essential to use aluminum hydroxide having a predetermined particle size or iron oxide having a predetermined particle size as in Patent Literatures 1 and 2. In addition, as the content of the thermally conductive powder increases, the viscosity in a high shear rate region increases, and the coatability also deteriorates. Furthermore, even when an organic peroxide is used as in Patent Literature 3, thermal conduction properties are impaired when the grease is cured and peels off from the object, and improvement in the drip resistance cannot be expected when the organic peroxide does not act, and thus, effective means for improving the drip resistance cannot be achieved.

The present invention has been made in view of the above problems, and an object thereof is to provide a thermally conductive grease excellent in drip resistance, thermal conduction properties, and coatability.

### Solution to Problem

As a result of intensive studies to solve the above problems, the present inventors have found that the above problems can be solved mainly by using predetermined two kinds of alkenyl group-containing organopolysiloxanes in combination and using a thermally conductive grease having a predetermined thixotropy, and thus completed the present invention.

That is, the present invention is as follows.

[1]

A thermally conductive grease comprising:
an alkenyl group-containing organopolysiloxane A having two or more alkenyl groups;
an alkenyl group-containing organopolysiloxane B having two or more alkenyl groups; and
a thermally conductive powder, in which
a viscosity ηA of the alkenyl group-containing organopolysiloxane A at 25° C. and a shear rate of 10 s⁻¹ is smaller than viscosity ηB of the alkenyl group-containing organopolysiloxane B at 25° C. and a shear rate of 10 s⁻¹, and
a ratio (Ti value) of viscosity η1 at a shear rate 1 s⁻¹ to viscosity η10 at 25° C. and a shear rate of 10 s⁻¹ is 3.0 or more.
   [2]

The thermally conductive grease according to [1], in which
a content of the alkenyl group-containing organopolysiloxane B is 3 to 30 parts by weight based on 100 parts by weight of the alkenyl group-containing organopolysiloxane A.
   [3]

The thermally conductive grease according to [1] or [2], in which
a content of the thermally conductive powder is 400 to 2,000 parts by weight based on 100 parts by weight of the alkenyl group-containing organopolysiloxane A.
   [4]

The thermally conductive grease according to any one of [1] to [3], in which
the viscosity ηA of the alkenyl group-containing organopolysiloxane A at 25° C. and a shear rate of 10 s⁻¹ is 50 to 1,000 mPa·s, and
the viscosity ηB of the alkenyl group-containing organopolysiloxane B at 25° C. and a shear rate of 10 s⁻¹ is 1,000,000 to 5,000,000 mPa·s.
   [5]

The thermally conductive grease according to any one of [1] to [4], in which
a ratio (ηB/ηA) of the viscosity ηB of the alkenyl group-containing organopolysiloxane B at 25° C. and a shear rate of 10 s⁻¹ to the viscosity ηA of the alkenyl group-containing organopolysiloxane A at 25° C. and a shear rate of 10 s⁻¹ is 1,000 to 25,000.
   [6]

The thermally conductive grease according to any one of [1] to [5], further comprising
organosilane, in which
a content of the organosilane is 0.01 parts by weight to 10 parts by weight based on 100 parts by weight of the alkenyl group-containing organopolysiloxane A.
   [7]

The thermally conductive grease according to any one of [1] to [6], in which
the alkenyl group-containing organopolysiloxane A contains two or more of the alkenyl groups at both terminals and/or at least one of side chains.
   [8]

The thermally conductive grease according to any one of [1] to [7], in which
the alkenyl group-containing organopolysiloxane B contains two or more of the alkenyl groups at both terminals and/or at least one of side chains.
   [9]

The thermally conductive grease according to any one of [1] to [8], in which
the thermally conductive powder comprises one or more selected from the group consisting of alumina, aluminum nitride, boron nitride, aluminum hydroxide, zinc oxide, silica, and metallic aluminum.
   [10]

The thermally conductive grease according to any one of [1] to [9], in which
the viscosity η10 at 25° C. and a shear rate of 10 s⁻¹ is 50 to 1,500 Pa·s, and
a thermal conductivity is 0.5 W/mK or more.
   [11]

An electronic device comprising:
a heat-generating element;
a metal housing; and
the thermally conductive grease according to any one of [1] to interposed between the heat-generating element and the metal housing.

### Advantageous Effects of Invention

According to the present invention, it is possible to provide a thermally conductive grease excellent in drip resistance, thermal conduction properties, and coatability.

### DESCRIPTION OF EMBODIMENTS

### 1. Thermally Conductive Grease

A thermally conductive grease of the present embodiment comprises an alkenyl group-containing organopolysiloxane A (hereinafter referred to as “organopolysiloxane A”) having two or more alkenyl groups, an alkenyl group-containing organopolysiloxane B (hereinafter referred to as “organopolysiloxane B”) having two or more alkenyl groups, and a thermally conductive powder. Viscosity ηA of the alkenyl group-containing organopolysiloxane A at 25° C. and a shear rate of 10 s⁻¹ is smaller than viscosity ηB of the alkenyl group-containing organopolysiloxane B at 25° C. and a shear rate of 10 s⁻¹, and a ratio (Ti value) of viscosity η1 at a shear rate 1 s⁻¹ to viscosity η10 at 25° C. and a shear rate of 10 s⁻¹ is 3.0 or more.

In the present invention, the organopolysiloxane A and the organopolysiloxane B are used in combination, and a thermally conductive grease having a predetermined thixotropy is used. As a result, it is possible to increase the viscosity in the low shear rate region, and decrease the viscosity in the high shear rate region, thereby achieving excellent drip resistance and coatability.

In particular, the dripping of the heat dissipation grease tends to easily occur as the thickness of the gap in which the heat dissipation grease is used increases. However, the thermally conductive grease of the present embodiment is excellent in the drip resistance even when the thickness is large. Therefore, when the thermally conductive grease of the present embodiment is used for the gap between the heat-generating element and the metal housing, the thickness of the gap may be 1.8 mm or more, 1.9 mm or more, or 2.0 mm or more.

The ratio (Ti value) of the viscosity η1 at the shear rate of 1 s⁻¹ to the viscosity η10 at 25° C. and a shear rate of 10 s⁻¹ of the thermally conductive grease is 3.0 or more, preferably 3.2 or more, more preferably 3.4 or more, and still more preferably 3.6 or more. The upper limit of the ratio (Ti value) is not particularly limited, but may be 10 or less. When the ratio (Ti value) of the viscosity η1 at a shear rate 1 s⁻¹ to the viscosity η10 is 3.0 or more, the drip resistance and the coatability are excellent.

The viscosity η10 of the thermally conductive grease at 25° C. and a shear rate of 10 s⁻¹ is preferably 50 to 1,500 Pa·s, the thermal conductivity is 0.5 W/mK or more, and the ratio (Ti value) of the viscosity η1 at a shear rate of 1 s⁻¹ to the viscosity η10 is 3.0 or more.

In the thermally conductive grease, the viscosity η10 at 25° C. and a shear rate of 10 s⁻¹ is preferably 50 to 1,500 Pa·s, more preferably 100 to 1,000 Pa·s, and still more preferably 150 to 1,000 Pa·s. When the viscosity η10 at 25° C. and a shear rate of 10 s⁻¹ is 50 Pas or more, it is possible to suppress dripping even for vertical placement. When the viscosity η10 is 1,500 Pa·s or less, the coatability tends to be excellent.

The viscosity η1 of the thermally conductive grease at 25° C. and a shear rate of 1 s⁻¹ is preferably 1,500 to 10,000 Pa·s, more preferably 2,500 to 8,000 Pa·s, and still more preferably 3,000 to 6,000 Pa·s. When the viscosity η1 is 1,500 Pas or more, there is a tendency to suppress dripping even for vertical placement. When the viscosity η1 is 10,000 Pas or less, the coatability tends to be excellent.

The thermal conductivity of the thermally conductive grease measured by the steady state method are preferably 0.5 W/mK or more, more preferably 1.0 W/mK or more, still more preferably 1.5 W/mK or more, and still more preferably 2.0 W/mK or more. When the thermal conductivity is 0.5 W/mK or more, excellent thermal conduction properties can be obtained, and good heat dissipation can be obtained for an electronic component.

Furthermore, in the present invention, the thermal conduction properties are not limited by the limitation of the type of the thermally conductive powder and the like as in Patent Literatures 1 and 2 described above.

In addition, since the thermally conductive grease of the present embodiment is a one-liquid type composition, it is not essential to introduce a two-liquid mixing and coating apparatus as in the case of a two-liquid type composition, the manufacturing step can be simplified, and the manufacturing cost tends to be excellent.

Hereinafter, each component of the thermally conductive grease of the present embodiment will be described in detail.

### 1.1. Alkenyl Group-Containing Organopolysiloxane A

The alkenyl group-containing organopolysiloxane A is a compound having a siloxane skeleton and two or more alkenyl groups. When the thermally conductive grease comprises the organopolysiloxane A, the viscosity in the high shear region can be reduced, and the coatability is excellent. The organopolysiloxane A is preferably liquid at room temperature from the viewpoint of coatability, and is preferably an addition reaction type from the viewpoint of coatability and drip resistance.

The organopolysiloxane A preferably comprises two or more alkenyl groups at both terminals and/or at least one of side chains, and more preferably comprises two alkenyl groups at at least both terminals. Accordingly, the drip resistance tends to be further improved. In addition, the organopolysiloxane A may be linear, branched, or cyclic, but is preferably linear. As a result, the drip resistance of the thermally conductive grease tends to be further improved.

The organopolysiloxane A may further contain a SiH group. In other words, the organopolysiloxane A may contain an organopolysiloxane A2 having an alkenyl group and a SiH group in addition to an organopolysiloxane A1 having only an alkenyl group. Among them, an embodiment comprising the organopolysiloxane A1 and the organopolysiloxane A2 is preferable. As a result, the viscosity n10, the viscosity n1, and the ratio (Ti value) are easily adjusted to the above ranges, and the drip resistance of the thermally conductive grease tends to be further improved.

In addition, the organopolysiloxanes A1 and A2 are not particularly limited, but for example, may have a constitutional unit represented by Formula (1) or a constitutional unit represented by Formula (2) as a constitutional unit having an alkenyl group, or may have a constitutional unit represented by Formula (3) as a constitutional unit not having an alkenyl group.

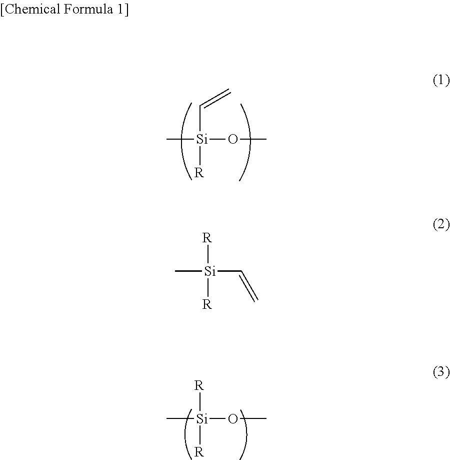

Here, in Formulas (1), (2), and (3), R is any monovalent hydrocarbon group which may have a substituent other than an alkenyl group. Such a monovalent hydrocarbon group is not particularly limited, and examples thereof include alkyl groups such as a methyl group, an ethyl group, a propyl group, a butyl group, a pentyl group, a hexyl group, a heptyl group, an octyl group, a nonyl group, a decyl group, and a dodecyl group; cycloalkyl groups such as cyclopentyl group and cyclohexyl group; aryl groups such as a phenyl group, a tolyl group, a xylyl group, and a naphthyl group; aralkyl groups such as a benzyl group, a 2-phenylethyl group, and a 2-phenylpropyl group; and a group having a substituent in these groups. Examples of the substituent of the monovalent hydrocarbon group include a halogen atom, particularly a fluorine atom or a chlorine atom.

In addition, the organopolysiloxane A2 preferably contains two or more SiH groups in at least one of both terminals and/or side chains, and more preferably contains a SiH group in the side chain. In addition, the organopolysiloxane A2 is not particularly limited, but for example, may have a constitutional unit represented by Formula (4) or a constitutional unit represented by Formula (5) as a constitutional unit having a SiH group, or may have a constitutional unit represented by Formula (6) as a constitutional unit not having a SiH group.

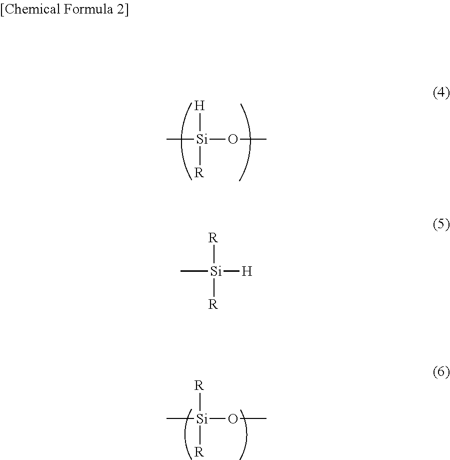

Here, in Formulas (4), (5), and (6), R is any monovalent hydrocarbon group which may have a substituent. Such a monovalent hydrocarbon group is not particularly limited, and examples thereof include alkyl groups such as a methyl group, an ethyl group, a propyl group, a butyl group, a pentyl group, a hexyl group, a heptyl group, an octyl group, a nonyl group, a decyl group, and a dodecyl group; cycloalkyl groups such as cyclopentyl group and cyclohexyl group; aryl groups such as a phenyl group, a tolyl group, a xylyl group, and a naphthyl group; aralkyl groups such as a benzyl group, a 2-phenylethyl group, and a 2-phenylpropyl group; and a group having a substituent in these groups. Examples of the substituent of the monovalent hydrocarbon group include a halogen atom, particularly a fluorine atom or a chlorine atom.

The viscosity ηA of the organopolysiloxane A measured with a rotary rheometer at 25° C. and a shear rate of 10 s⁻¹ is preferably 50 to 1,000 mPa·s, more preferably 100 to 800 mPa·s, and still more preferably 150 to 600 mPa·s. When the viscosity ηA is 50 mPa·s or more, the drip resistance of the thermally conductive grease tends to be excellent, and when the viscosity ηA is 1,000 mPa·s or less, the coatability tends to be excellent.

When the organopolysiloxane A contains a plurality of components such as the organopolysiloxanes A1 and A2, each component satisfies the viscosity.

The content of the organopolysiloxane A is preferably 1.0 to 30% by weight, more preferably 3.0 to 20% by weight, and still more preferably 6.0 to 12% by weight based on the total amount of the thermally conductive grease. When the content of the organopolysiloxane A is 1.0% by weight or more, the drip resistance tends to be excellent, and when the content of the organopolysiloxane A is 30% by weight or less, the coatability tends to be excellent.

### 1.2. Alkenyl Group-Containing Organopolysiloxane B

The alkenyl group-containing organopolysiloxane B is a compound having a siloxane skeleton and two or more alkenyl groups. When the thermally conductive grease comprises the organopolysiloxane B, the viscosity in the low shear region can be improved, and the drip resistance is excellent. The organopolysiloxane B is preferably liquid at room temperature from the viewpoint of coatability, and is preferably an addition reaction type from the viewpoint of coatability and drip resistance.

Among them, the organopolysiloxane B preferably contains two or more alkenyl groups at both terminals and/or at least one of side chains, and more preferably contains two alkenyl groups at at least both terminals. Accordingly, the drip resistance tends to be further improved. In addition, the organopolysiloxane B may be linear, branched, or cyclic, but is preferably linear. As a result, the drip resistance of the thermally conductive grease tends to be further improved.

The organopolysiloxane B is not particularly limited, but for example, may have a constitutional unit represented by the above-described Formula (1) or a constitutional unit represented by the above-described Formula (2) as a constitutional unit having an alkenyl group, or may have a constitutional unit represented by the above-described Formula (3) as a constitutional unit not having an alkenyl group.

The viscosity ηB of the organopolysiloxane B measured with a rotary rheometer at 25° C. and a shear rate of 10 s⁻¹ is preferably 500,000 to 10,000,000 mPa·s, more preferably 1,000,000 to 5,000,000 mPa·s, and still more preferably 1,000,000 to 3,500,000 mPa·s. When the viscosity ηB is 500,000 mPa·s or more, the drip resistance of the thermally conductive grease tends to be excellent, and when the viscosity ηB is 10,000,000 mPa's or less, the coatability tends to be excellent.

The content of the organopolysiloxane B is preferably 0.3 to 3.0% by weight, more preferably 0.5 to 2.5% by weight, still more preferably 0.7 to 2.0% by weight, and particularly preferably 1.0 to 2.0% by weight based on the total amount of the thermally conductive grease. When the content of the organopolysiloxane B is 0.3% by weight or more, the drip resistance tends to be excellent, and when the content of the organopolysiloxane B is 0.3% by weight or less, the coatability tends to be excellent.

In addition, the content of the organopolysiloxane B is preferably 3 to 30 parts by weight, more preferably 5 to 25 parts by weight, and still more preferably 10 to 20 parts by weight based on 100 parts by weight of the organopolysiloxane A. When the content of the organopolysiloxane B is 3 parts by weight or more based on 100 parts by weight of the organopolysiloxane A, the drip resistance tends to be excellent, and when the content of the organopolysiloxane B is 30 parts by weight or less based on 100 parts by weight of the organopolysiloxane A, the coatability tends to be excellent.

The ratio (ηB/ηA) of the viscosity ηB to the viscosity ηA is preferably 1,000 to 25,000, more preferably 1,500 to 15,000, still more preferably 2,000 to 10,000, and still more preferably 2,500 to 5,000. When ηB/ηA is 1,000 or more, the drip resistance tends to be excellent, and when ηB/ηA is 25,000 or less, the coatability tends to be excellent.

### 1.3. SiH Group-Containing Organohydrogen Polysiloxane

The thermally conductive grease of the present embodiment may comprise SiH group-containing organohydrogen polysiloxane (hereinafter also simply referred to as “organopolysiloxane C”). The organohydrogen polysiloxane is a compound having a siloxane skeleton and having two or more SiH groups. In addition, the organopolysiloxane C does not contain an alkenyl group, and refers to those other than the organopolysiloxanes A and B.

The SiH group of the organopolysiloxane C and the alkenyl group of the organopolysiloxanes A and B can undergo an addition reaction or the like. As a result, in the thermally conductive grease of the present embodiment, the organopolysiloxanes A and B having different chain lengths, that is, viscosities, and the organopolysiloxane C are crosslinked in a three-dimensional network, a predetermined ratio (Ti value) can be satisfied, and the grease is excellent in drip resistance.

The organopolysiloxane C preferably contains two or more SiH groups at both terminals and/or at least one of side chains. Accordingly, the drip resistance tends to be further improved. In addition, the organopolysiloxane C may be linear, branched, or cyclic, but is preferably linear. As a result, the drip resistance of the thermally conductive grease tends to be further improved.

In addition, the organopolysiloxane C is not particularly limited, but for example, may have a constitutional unit represented by Formula (4) or a constitutional unit represented by Formula (5) as a constitutional unit having a SiH group, or may have a constitutional unit represented by Formula (6) as a constitutional unit not having a SiH group.

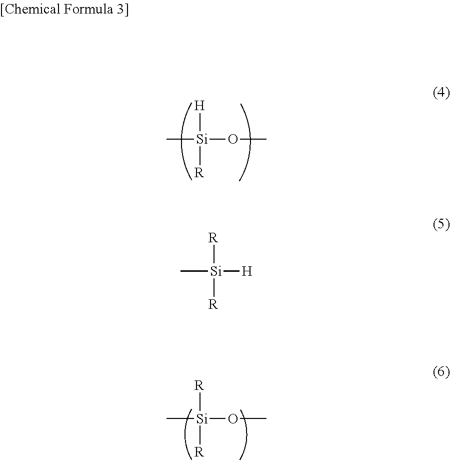

Here, in Formulas (4), (5), and (6), R is any monovalent hydrocarbon group which may have a substituent. Such a monovalent hydrocarbon group is not particularly limited, and examples thereof include alkyl groups such as a methyl group, an ethyl group, a propyl group, a butyl group, a pentyl group, a hexyl group, a heptyl group, an octyl group, a nonyl group, a decyl group, and a dodecyl group; cycloalkyl groups such as cyclopentyl group and cyclohexyl group; aryl groups such as a phenyl group, a tolyl group, a xylyl group, and a naphthyl group; aralkyl groups such as a benzyl group, a 2-phenylethyl group, and a 2-phenylpropyl group; and a group having a substituent in these groups. Examples of the substituent of the monovalent hydrocarbon group include a halogen atom, particularly a fluorine atom or a chlorine atom.

The viscosity ηC of the organopolysiloxane C measured with a rotary rheometer at 25° C. and a shear rate of 10 s⁻¹ is preferably 1 to 1,000 mPa·s, more preferably 5 to 500 mPa·s, and still more preferably 10 to 100 mPa·s. When the organopolysiloxane viscosity ηC is 1 mPa's or more, the thermally conductive grease can be uniformly cured, and the drip resistance tends to be excellent. When the organopolysiloxane viscosity ηC is 1,000 mPa's or less, the coatability tends to be excellent.

The ratio X of the number of SiH groups in the molecule of the organopolysiloxane C to the sum of the number of alkenyl groups in the molecule of the organopolysiloxane A and the number of alkenyl groups in the molecule of the organopolysiloxane B is preferably 0.2 to 1.0. When the ratio X is 0.2 or more, the thermally conductive grease tends to exhibit excellent drip resistance, and when the ratio X is 1.0 or less, the coatability tends to be excellent.

The content of the organopolysiloxane C is preferably 0.1 to 5% by weight, more preferably 0.3 to 3% by weight, and still more preferably 0.5 to 1% by weight based on the total amount of the thermally conductive grease. When the content of the organopolysiloxane C is 0.1% by weight or more, the drip resistance tends to be excellent, and when the content of the organopolysiloxane C is 5% by weight or less, the coatability tends to be excellent.

The content of the organopolysiloxane C is preferably 1 to 30 parts by weight, more preferably 5 to 20 parts by weight, and still more preferably 7.5 to 15 parts by weight based on 100 parts by weight of the organopolysiloxane A. When the content of the organopolysiloxane C is 1 parts by weight or more, the drip resistance tends to be excellent, and when the content is 30 parts by weight or less, the coatability tends to be excellent.

### 1.4. Thermally Conductive Powder

Since the thermally conductive grease comprises the thermally conductive powder, the thermal conductivity of the thermally conductive grease can be improved.

The shape of the thermally conductive powder is not particularly limited, and examples thereof include a spherical shape, an elliptical shape, and an irregular shape. Among them, a spherical shape is preferable from the viewpoint of achieving low viscosity at high filling levels and exhibiting excellent coatability.

The average particle size of the thermally conductive powder is preferably 0.1 to 100 μm, more preferably 0.2 to 80 μm, and still more preferably 0.3 to 60 μm. When the average particle size of the thermally conductive powder is within the above range, the thermally conductive powder can be highly filled and tends to sufficiently exhibit thermal conduction properties.

The thermally conductive powder preferably comprises a metal oxide, and examples of such a metal oxide include, but are not particularly limited to, alumina, aluminum nitride, boron nitride, aluminum hydroxide, zinc oxide, silica, and metallic aluminum. Among them, from the viewpoint of high thermal conduction properties, coatability, and cost, it is more preferable to contain one or more of alumina, zinc oxide, silica, and metallic aluminum, and it is still more preferable to contain at least one selected from alumina and silica. The thermally conductive powder may be used alone or in combination of two or more thereof. When two or more kinds of thermally conductive powders are used in combination, it is preferable to use at least alumina and silica in combination.

The content of the thermally conductive powder is preferably 60 to 96% by weight, more preferably 70 to 95% by weight, still more preferably 80 to 94% by weight, and still more preferably 85 to 93% by weight based on the total amount of the thermally conductive grease. When the content of the thermally conductive powder is 60% by weight or more, the drip resistance and the thermal conduction properties tend to be excellent, and when the content of the thermally conductive powder is 96% by weight or less, the coatability tends to be excellent.

In addition, the content of the thermally conductive powder is preferably 100 to 2,000 parts by weight, more preferably 300 to 1,500 parts by weight, and still more preferably 600 to 1,000 parts by weight based on 100 parts by weight in total of the organopolysiloxane A and the organopolysiloxane B. When the content of the thermally conductive powder is 100 parts by weight or more based on 100 parts by weight in total of the organopolysiloxane A and the organopolysiloxane B, the thermal conduction properties and the drip resistance tend to be excellent. In addition, when the content of the thermally conductive powder is 2,000 parts by weight or less based on 100 parts by weight in total of the organopolysiloxane A and the organopolysiloxane B, the viscosity of the thermally conductive grease to be obtained can be reduced, and the coatability tends to be excellent.

In addition, the content of the thermally conductive powder is preferably 400 to 2,000 parts by weight, more preferably 600 to 1,500 parts by weight, and still more preferably 800 to 1,200 parts by weight based on 100 parts by weight of the organopolysiloxane A. When the content of the thermally conductive powder is 400 parts by weight or more based on 100 parts by weight of the organopolysiloxane A, the thermal conduction properties and the drip resistance tend to be excellent, and when the content of the thermally conductive powder is 2,000 parts by weight or less based on 100 parts by weight of the organopolysiloxane A, the coatability tends to be excellent.

### 1.5. Addition Reaction Catalyst

The thermally conductive grease of the present embodiment preferably comprises an addition reaction catalyst. The addition reaction catalyst is not particularly limited as long as the addition reaction catalyst catalyzes the addition reaction between the organopolysiloxanes A and B and the organopolysiloxane C. Examples of the addition reaction catalyst include a platinum catalyst, a rhodium catalyst, and a palladium catalyst.

When the thermally conductive grease comprises an addition reaction catalyst, the addition reaction between the organopolysiloxane A and the organopolysiloxane B can be promoted, the addition reaction of the organopolysiloxane C to the organopolysiloxane A or the organopolysiloxane B can be promoted, and a good thermally conductive grease having excellent drip resistance can be formed.

The content of the addition reaction catalyst is preferably 1 to 300 ppm, and more preferably 50 to 100 ppm based on the total amount of the thermally conductive grease. When the content of the addition reaction catalyst is within the above range, the effect as a catalyst can be sufficiently obtained, and the drip resistance tends to be excellent.

As the addition reaction catalyst, a platinum catalyst is preferable. The platinum catalyst is not particularly limited, and examples thereof include simple platinum, a platinum compound, and a platinum-supported inorganic powder. The platinum compound is not particularly limited, and examples thereof include chloroplatinic acid, a platinum-olefin complex, a platinum-alcohol complex, and a platinum coordination compound. The platinum-supported inorganic powder is not particularly limited, and examples thereof include platinum-supported alumina powder, platinum-supported silica powder, and platinum-supported carbon powder.

The content of the platinum catalyst is preferably 0.001 to 0.330 parts by weight, and more preferably 0.01 to 0.20 parts by weight based on 100 parts by weight of the content of the organopolysiloxane A. When the content of the platinum catalyst is within the above range, the effect as a catalyst can be sufficiently obtained, and the drip resistance tends to be excellent.

### 1.6. Organosilane

The thermally conductive grease of the present embodiment preferably comprises an organosilane. The organosilane is a compound in which an organic group is bonded to silicon, and is preferably represented by the following Formula (F1).

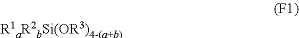

When the thermally conductive grease comprises an organosilane, wettability between the organopolysiloxane A or the organopolysiloxane B and the thermally conductive powder can be improved.

In Formula (F1), R¹ is an alkyl group having 1 to 15 carbon atoms, and preferably an alkyl group having 6 to 12 carbon atoms. R¹ is not particularly limited, and examples thereof include a methyl group, an ethyl group, a propyl group, a hexyl group, a nonyl group, a decyl group, a dodecyl group, and a tetradecyl group.

R² is a saturated or unsaturated monovalent hydrocarbon group having 1 to 8 carbon atoms. R² is not particularly limited, and examples thereof include alkyl groups such as a methyl group, an ethyl group, a propyl group, a hexyl group, and an octyl group; cyclohexyl groups such as a cyclopentyl group and a cyclohexyl group; alkenyl groups such as a vinyl group and an allyl group; aryl groups such as a phenyl group and a tolyl group; aralkyl groups such as a 2-phenylethyl group and a 2-methyl-2-phenylethyl group; and halogenated hydrocarbon groups such as a 3,3,3-trifluoropropyl group, a 2-(perfluorobutyl)ethyl group, a 2-(perfluorooctyl)ethyl group, and a p-chlorophenyl group.

R³ is one or more alkyl groups having 1 to 6 carbon atoms, and is not particularly limited, and examples thereof include a methyl group, an ethyl group, a propyl group, a butyl group, a pentyl group, and a hexyl group. Among them, a methyl group or an ethyl group is preferable.

a is an integer of 1 to 3, preferably 1. b is an integer of 0 to 2, preferably 0. In addition, a+b is an integer of 1 to 3, preferably 1.

The content of the organosilane is preferably 0.01 to 10 parts by weight, more preferably 0.1 to 5.0 parts by weight, and still more preferably 1.0 to 4.0 parts by weight based on 100 parts by weight of the content of the organopolysiloxane A. When the content of the organosilane is within the above range, wettability can be effectively improved.

### 1.7. Other Components

The thermally conductive grease of the present embodiment may contain other components as necessary. The other components are not particularly limited, and examples thereof include resins, colorants, and reaction retarders other than those described above. When the thermally conductive grease comprises a colorant, the content of the colorant is 0.05 to 0.5% by weight based on to the total amount of the thermally conductive grease.

### 1.8. Manufacturing Method

The method for manufacturing the thermally conductive grease of the present embodiment includes: a mixing step of mixing the organopolysiloxane A and the organopolysiloxane B to obtain a cured product; and a shearing force applying step of applying a shearing force to the cured product to grease the cured product, and may include other steps as necessary. The other steps are not particularly limited, and examples thereof include a heating step of heating the mixture after the mixing step and before the shearing force applying step.

By the mixing step, the organopolysiloxane A and the organopolysiloxane B can be reacted and cured. At this time, the curing reaction can be promoted by performing the heating step. Then, by the shearing force applying step, a shear stress is applied to the cured product to grease the cured product, and a thermally conductive grease can be obtained.

### 2. Electronic Device

The electronic device of the present embodiment includes a heat-generating element, a metal housing, and the thermally conductive grease of the present embodiment interposed between the heat-generating element and the metal housing.

The heat-generating element is not particularly limited, and examples thereof include an electron tube, a semiconductor element, a resistor, a capacitor, and a condenser.

The metal constituting the metal housing is not particularly limited, and examples thereof include steel, tool steel, carbon steel, iron, stainless steel, aluminum, nickel, magnesium, titanium, copper, and alloys containing these metals.

As a method for preparing the electronic device, a conventionally known method can be used, and is not particularly limited, but for example, the electronic device can be obtained by a manufacturing method including: a step of applying a thermally conductive grease to a surface of a heat-generating element to form a coating layer made of the thermally conductive grease on the surface; and a step of pressure-welding and fixing the coating layer and the heat-generating element.

### EXAMPLES

Hereinafter, the present invention will be described more specifically using examples and comparative examples. The present invention is not limited at all by the following examples.

### 1. Preparation of Thermally Conductive Grease

The components contained in the thermally conductive greases of Examples and Comparative Examples are as follows.

### <Alkenyl Group-Containing Organopolysiloxane A>

Vinyl group-containing organopolysiloxane A-1a: product name “XE14-B8530 (A)” (manufactured by Momentive Performance Materials Inc.), both terminal vinyl group-containing organopolysiloxane, viscosity measured with a rotary rheometer at 25° C. and a shear rate of 10 s⁻¹: 230 mPa·s
Vinyl group-containing organopolysiloxane A-1b: product name “XE14-B8530 (B)” (manufactured by Momentive Performance Materials Inc.), both terminal vinyl group-containing organopolysiloxane, viscosity measured with a rotary rheometer at 25° C. and a shear rate of 10 s⁻¹: 500 mPa·s, average number of hydrosilyl groups: 2)
Vinyl group-containing organopolysiloxane A-2a: product name “SE-1885 (A)” (manufactured by Dow Corning Toray Co., Ltd.), both terminal vinyl group-containing organopolysiloxane, viscosity measured with a rotary rheometer at 25° C. and a shear rate of 10 s⁻¹: 490 mPa·s
Vinyl group-containing organopolysiloxane A-2b: product name “SE-1885 (B)” (manufactured by Dow Corning Toray Co., Ltd.), both terminal vinyl group-containing organopolysiloxane, viscosity measured with a rotary rheometer at 25° C. and a shear rate of 10 s⁻¹: 370 mPa·s, average number of hydrosilyl groups: 4)

### <Alkenyl Group-Containing Organopolysiloxane B>

Vinyl group-containing organopolysiloxane B-1: product name “SRH-32” (manufactured by Momentive Performance Materials Inc.), both terminal vinyl group-containing organopolysiloxane, viscosity measured with a rotary rheometer at 25° C. and a shear rate of 10 s⁻¹: 1,200,000 mPa·s

### <Thermally Conductive Powder>

Alumina 1: product name “DAW-45S” (manufactured by Denka Company Limited), alumina powder, average particle size: 45 μm, spherical shape
Alumina 2: “DAW-20” (manufactured by Denka Company Limited), alumina powder, average particle size: 20 μm, spherical shape
Alumina 3: “AES-23” (manufactured by Sumitomo Chemical Co., Ltd.), alumina powder, average particle size: 2.2 μm, spindle shape
Alumina 4: “AA-05” (manufactured by Sumitomo Chemical Co., Ltd.), alumina powder, average particle size: 0.5 μm, spherical shape
Silica 1: “FB-5D” (manufactured by Denka Company Limited), silica powder, average particle size: 5 μm, spherical shape
Silica 2: “5X” (manufactured by Tatsumori Co., Ltd.), silica powder, average particle size: 0.5 μm, spherical shape
Zinc oxide 1: “Zinc Oxide (Type 1)” (manufactured by Honjo Chemical Corporation), zinc oxide powder, average particle size: 0.5 μm, spherical shape

### <Organosilane>

Decyltrimethoxysilane: product name “n-decyltrimethoxysilane Z-6210” (manufactured by Dow Chemical Company)

### <Pigment>

Resino black: product name “Resino Black” (manufactured by Resino Color Industry Co., Ltd.)

Each of the above components was mixed and stirred to have the composition described in Table 1 to 2 to obtain a thermally conductive grease of each Example and each Comparative Example. The obtained thermally conductive grease was evaluated by the following evaluation method. The content (% by weight) of each component in Tables 1 and 2 represents the solid concentration.

### 2. Preparation of Thermally Conductive Grease

Into a 2 L TRI-MIX (manufactured by INOUE MFG., INC.) vessel, the vinyl group-containing polydimethylsiloxane A, the vinyl group-containing polydimethylsiloxane B, the organosilane, and the pigment were charged according to the compositions shown in Tables 1 and 2. The mixture was stirred at room temperature and normal pressure for 5 minutes, then a half amount of the thermally conductive powder was mixed, and the mixture was stirred at room temperature and reduced pressure for 5 minutes. Subsequently, the remaining total amount of the thermally conductive powder was mixed, and mixing was performed for 5 minutes at room temperature and reduced pressure. The internal temperature of the vessel was raised to 110° C., and the temperature was raised to 110° C. and then held for 3 hours to terminate the reaction. Thereafter, the temperature was returned to room temperature, and the mixture was stirred and mixed for 60 minutes under reduced pressure to obtain a thermally conductive grease.

### 3. Evaluation

### 3.1. Average Particle Size

The average particle size of the thermally conductive powder was measured using a “laser diffraction particle size distribution analyzer SALD-20” manufactured by Shimadzu Corporation. For the evaluation sample, 50 ml of pure water and 5 g of each filler component to be measured were added to a glass beaker, stirred using a spatula, and then subjected to a dispersion treatment for 10 minutes using an ultrasonic cleaner. The solution of the thermally conductive filler powder subjected to the dispersion treatment was added dropwise to the sampler portion of the device using a dropper, and the measurement was performed when the absorbance was stabilized. In the laser diffraction particle size distribution measuring apparatus, a particle size distribution is calculated from data of a light intensity distribution of diffraction/scattering holes by particles detected by a sensor. The average particle size is determined by multiplying the value of the measured particle size by the relative particle amount (difference %) and dividing the result by the sum of the relative particle amounts (100%). The average particle size is the average diameter of the particles, and can be obtained as a cumulative weight average value D50 (or a median diameter) which is a maximum value or a peak value. Note that D50 is the particle size having the largest appearance rate. The average particle size of each thermally conductive powder obtained by the measurement is shown in Tables 1 and 2.

### 3.2. Viscosity

The viscosity of the thermally conductive grease of each of Examples and Comparative Examples was measured using a rotary rheometer “HANKE MARSIII” (manufactured by Thermo Fisher Scientific) under the conditions of a gap of 0.5 mm, a temperature of 25° C., and a shear rate of 1 s⁻¹ or 10 s⁻¹ using a parallel plate having a diameter of 35 mmφ.

### 3.3. Coatability

Regarding the coatability of the thermally conductive grease, in view of the fact that the measured value cannot be obtained by the above measurement when the viscosity exceeds a predetermined value, coatability was evaluated according to the following evaluation criteria. The results obtained for each of Examples and Comparative Examples are shown in Tables 1 and 2.

### [Evaluation Criteria]

◯: Viscosity (Pas) at 25° C. and a shear rate of 10 s⁻¹ could be measured.
x: Viscosity (Pa·s) at 25° C. and a shear rate of 10 s⁻¹ could not be measured.

### 3.4. Thermal Conduction Properties

The thermal conductivity of the thermally conductive grease was measured by a method in accordance with ASTM D5470 using a resin material thermal resistance measuring apparatus (manufactured by Hitachi Solutions Technology, Ltd.). Specifically, the thermally conductive grease was sandwiched between copper jigs having thicknesses of 0.2 mm, 0.5 mm, and 1.0 mm and an area of 10 mm×10 mm, and the thermal resistance value for each thickness was measured. The thermal conductivity of the thermally conductive grease was calculated from the following Formula 1 from the inclination L of the straight line obtained with the thermal resistance value (° C./W) as the vertical axis and the thickness (mm) of the thermally conductive grease as the horizontal axis.

$$Thermal conductivity ( W / mK ) = 10 / L \qquad ( 1 )$$

The results obtained for each of Examples and Comparative Examples are shown in Tables 1 and 2.

### 3.5. Drip Resistance

For the drip resistance of the thermally conductive grease, 2 mm-thick spacers were installed at four corners of a 80 mm×80 mm×3 mmt glass plate, the thermally conductive grease was applied to the central portion of the glass plate, and a test specimen was prepared by sandwiching the glass plate with another 80 mm×80 mm×3 mmt aluminum plate (two types were tested: surface roughness of 12.5 S and 25 S). The application amount of the thermally conductive grease was set to an amount such that the size of the circular shape of the mixture formed when sandwiched with the glass plates was 25 mmφ, the glass plates were fixed with clips and left standing vertically, and the mixture was charged into a heat cycle tank at −40° C. (30 minutes)=>125° C. (30 minutes), and after a lapse of 2,000 hours, the displacement of the thermally conductive grease from the initial position was visually observed. Then, the drip resistance was evaluated according to the following evaluation criteria. The results obtained for each of Examples and Comparative Examples are shown in Tables 1 and 2.

### [Evaluation Criteria]

⊙: There was no displacement at all after 2,000 hours.
◯: There was a displacement after 2,000 hours, but the displacement was within 1 mm.
x: There was a displacement after 2,000 hours, and the displacement exceeded 1 mm.

TABLE 1

| | | | Example | | | | | | |
|---|---|---|---|---|---|---|---|---|---|
| | | Unit | 1 | 2 | 3 | 4 | 5 | 6 | 7 |
| Alkenyl group- | Vinyl group-containing | % by | 4.56 | | 5.10 | 4.13 | 3.05 | 15.04 | 6.73 |
| containing | organopolysiloxane A-1a | weight | | | | | | | |
| organopolysiloxane | Vinyl group-containing | % by | 4.56 | | 5.10 | 4.13 | 3.05 | 10.03 | 4.48 |
| A | organopolysiloxane A-1b | weight | | | | | | | |
| | Vinyl group-containing | % by | | 4.56 | | | | | |
| | organopolysiloxane A-2a | weight | | | | | | | |
| | Vinyl group-containing | % by | | 4.56 | | | | | |
| | organopolysiloxane A-2b | weight | | | | | | | |
| Alkenyl group- | Vinyl group-containing | % by | 1.59 | 1.59 | 0.52 | 2.44 | 1.07 | 1.30 | 0.58 |
| containing | organopolysiloxane B-1 | weight | | | | | | | |
| organopolysiloxane | | | | | | | | | |
| B | | | | | | | | | |
| Thermally | Alumina 1 | % by | | | | | | | 48.40 |
| conductive powder | | weight | | | | | | | |
| | Alumina 2 | % by | 35.30 | 35.30 | 35.30 | 35.31 | 36.71 | | |
| | | weight | | | | | | | |
| | Alumina 3 | % by | 29.95 | 29.95 | 29.94 | 29.95 | 31.14 | | 26.40 |
| | | weight | | | | | | | |
| | Alumina 4 | % by | | | | | | | 13.20 |
| | | weight | | | | | | | |
| | Silica 1 | % by | 21.28 | 21.28 | 21.28 | 21.28 | 22.14 | | |
| | | weight | | | | | | | |
| | Silica 2 | % by | 2.48 | 2.48 | 2.48 | 2.48 | 2.58 | | |
| | | weight | | | | | | | |
| | Zinc oxide 1 | % by | | | | | | 72.60 | |
| | | weight | | | | | | | |
| | Total amount of thermally | % by | 89.0 | 89.0 | 89.0 | 89.0 | 92.6 | 72.6 | 88.0 |
| | conductive powder | weight | | | | | | | |
| Organosilane | Decyltrimethoxysilane | % by | 0.18 | 0.18 | 0.18 | 0.18 | 0.17 | 1.03 | 0.21 |
| | | weight | | | | | | | |
| Pigment | Resino black | % by | 0.10 | 0.10 | 0.10 | 0.10 | 0.09 | | |
| | | weight | | | | | | | |

| | | | | | | | | |
|---|---|---|---|---|---|---|---|---|
| Viscosity of cured product at 25° C. and | Pa · s | 850 | 1000 | 600 | 1050 | 1200 | 500 | 800 |
| shear rate of 10 s⁻¹ | | | | | | | | |
| Viscosity of cured product at 25° C. and | Pa · s | 2700 | 3300 | 1900 | 4500 | 4800 | 1700 | 2500 |
| shear rate of 1 s⁻¹ | | | | | | | | |
| Ti value | — | 3.2 | 3.3 | 3.2 | 4.3 | 4.0 | 3.4 | 3.1 |

| | | | | | | | | |
|---|---|---|---|---|---|---|---|---|
| Evaluation | Coatability | ◯ | ◯ | ◯ | ◯ | ◯ | ◯ | ◯ |
| | Thermal conductivity (W/mk) | 1.7 | 1.6 | 1.8 | 1.6 | 3.1 | 0.6 | 2.9 |
| | Drip resistance | ⊙ | ⊙ | ⊙ | ⊙ | ⊙ | ⊙ | ⊙ |

TABLE 2

| | | | Comparative Example | | | |
|---|---|---|---|---|---|---|
| | | Unit | 1 | 2 | 3 | 4 |
| Alkenyl group-containing | Vinyl group-containing | % by | 5.26 | | 10.03 | 2.71 |
| organopolysiloxane A | organopolysiloxane A-1a | weight | | | | |
| | Vinyl group-containing | % by | 5.26 | | 10.03 | 2.71 |
| | organopolysiloxane A-1b | weight | | | | |
| | Vinyl group-containing | % by | | 3.75 | | |
| | organopolysiloxane A-2a | weight | | | | |
| | Vinyl group-containing | % by | | 3.75 | | |
| | organopolysiloxane A-2b | weight | | | | |
| Alkenyl group-containing | Vinyl group-containing | % by | 0.20 | 3.19 | 3.50 | 0.94 |
| organopolysiloxane B | organopolysiloxane B-1 | weight | | | | |
| Thermally conductive | Alumina 1 | % by | | | | |
| powder | | weight | | | | |
| | Alumina 2 | % by | 35.30 | 35.31 | 30.17 | 37.04 |
| | | weight | | | | |
| | Alumina 3 | % by | 29.94 | 29.95 | 25.61 | 31.42 |
| | | weight | | | | |
| | Alumina 4 | % by | | | | |
| | | weight | | | | |
| | Silica 1 | % by | 21.28 | 21.29 | 18.20 | 22.33 |
| | | weight | | | | |
| | Silica 2 | % by | 2.48 | 2.48 | 2.12 | 2.60 |
| | | weight | | | | |
| | Zinc oxide 1 | % by | | | | |
| | | weight | | | | |
| | Total amount of thermally | % by | 89.0 | 89.0 | 76.1 | 93.4 |
| | conductive powder | weight | | | | |
| Organosilane | Decyltrimethoxysilane | % by | 0.18 | 0.18 | 0.22 | 0.16 |
| | | weight | | | | |
| Pigment | Resino black | % by | 0.10 | 0.10 | 0.12 | 0.09 |
| | | weight | | | | |

| | | | | | |
|---|---|---|---|---|---|
| Viscosity of cured product at 25° C. and | Pa · s | 450 | X*¹ | 350 | X*¹ |
| shear rate of 10 s⁻¹ | | | | | |
| Viscosity of cured product at 25° C. and | Pa · s | 1200 | X*¹ | 500 | X*¹ |
| shear rate of 1 s⁻¹ | | | | | |
| Ti value | — | 2.7 | — | 1.4 | — |

| | | | | | |
|---|---|---|---|---|---|
| Evaluation | Coatability | ◯ | X | ◯ | X |
| | Thermal conductivity (W/mk) | 1.7 | 1.5 | 0.4 | 3.1 |
| | Drip resistance | X | ⊙ | X | ⊙ |

*¹Measurement is not possible.

### 4. Evaluation Results

From the evaluation results shown in Tables 1 and 2, it was found that all of Examples 1 to 7 was excellent in both of the drip resistance and the coatability as compared with Comparative Examples 1 to 4 in which it was impossible to measure whether the Ti value was less than 3.0.

### INDUSTRIAL APPLICABILITY

The present invention has industrial applicability as a thermally conductive grease used in electronic devices and the like.

1. A thermally conductive grease comprising:
an alkenyl group-containing organopolysiloxane A having two or more alkenyl groups;
an alkenyl group-containing organopolysiloxane B having two or more alkenyl groups; and
a thermally conductive powder, wherein
a viscosity ηA of the alkenyl group-containing organopolysiloxane A at 25° C. and a shear rate of 10 s⁻¹ is smaller than viscosity ηB of the alkenyl group-containing organopolysiloxane B at 25° C. and a shear rate of 10 s⁻¹, and
a ratio (Ti value) of viscosity η1 at a shear rate 1 s⁻¹ to viscosity η10 at 25° C. and a shear rate of 10 s⁻¹ is 3.0 or more.

2. The thermally conductive grease according to claim 1, wherein
a content of the alkenyl group-containing organopolysiloxane B is 3 to 30 parts by weight based on 100 parts by weight of the alkenyl group-containing organopolysiloxane A.

3. The thermally conductive grease according to claim 1, wherein
a content of the thermally conductive powder is 400 to 2,000 parts by weight based on 100 parts by weight of the alkenyl group-containing organopolysiloxane A.

4. The thermally conductive grease according to claim 1, wherein
the viscosity ηA of the alkenyl group-containing organopolysiloxane A at 25° C. and a shear rate of 10 s⁻¹ is 50 to 1,000 mPa's, and
the viscosity ηB of the alkenyl group-containing organopolysiloxane B at 25° C. and a shear rate of 10 s⁻¹ is 1,000,000 to 5,000,000 mPa·s.

5. The thermally conductive grease according to claim 1, wherein
a ratio (ηB/ηA) of the viscosity ηB of the alkenyl group-containing organopolysiloxane B at 25° C. and a shear rate of 10 s⁻¹ to the viscosity ηA of the alkenyl group-containing organopolysiloxane A at 25° C. and a shear rate of 10 s⁻¹ is 1,000 to 25,000.

6. The thermally conductive grease according to claim 1, further comprising organosilane, wherein
a content of the organosilane is 0.01 parts by weight to 10 parts by weight based on 100 parts by weight of the alkenyl group-containing organopolysiloxane A.

7. The thermally conductive grease according to claim 1, wherein
the alkenyl group-containing organopolysiloxane A contains two or more of the alkenyl groups at both terminals and/or at least one of side chains.

8. The thermally conductive grease according to claim 1, wherein
the alkenyl group-containing organopolysiloxane B contains two or more of the alkenyl groups at both terminals and/or at least one of side chains.

9. The thermally conductive grease according to claim 1, wherein
the thermally conductive powder comprises one or more selected from the group consisting of alumina, aluminum nitride, boron nitride, aluminum hydroxide, zinc oxide, silica, and metallic aluminum.

10. The thermally conductive grease according to claim 1, wherein
the viscosity n10 at 25° C. and a shear rate of 10 s⁻¹ is 50 to 1,500 Pa·s, and
a thermal conductivity is 0.5 W/mK or more.

11. An electronic device comprising:
a heat-generating element;
a metal housing; and
the thermally conductive grease according to claim 1 interposed between the heat-generating element and the metal housing.
